(19) United States
(12) Patent Application Publication
(10) Pub. No.: US 2004/0175504 A1
(43) Pub. Date: Sep. 9, 2004

(54) Substrate processing apparatus and method for the controlled formation of layers including self-assembled monolayers

(75) Inventors: Markus Hasselblatt, Foster City, CA (US); Peter Wagner, Redwood City, CA (US); Peter Kernen, Foster City, CA (US); Frank Zaugg, Belmont, CA (US); Olivier de la Salle, Belmont, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Zyomyx, Inc.

(21) Appl. No.: 10/384,187

(22) Filed: Mar. 6, 2003

(51) Int. Cl. B05D 3/00; H01L 21/311; H01L 21/31; H01L 21/469

(52) U.S. Cl. 427/354; 438/700; 438/758; 438/778; 427/352

(57) ABSTRACT

Substrate processing methods and apparatuses are disclosed. One embodiment of the invention is directed to a substrate processing apparatus for processing an analytical substrate. The apparatus includes a substrate holder for holding a substrate and a processing chamber including an opening for receiving the substrate holder and the substrate. A fluid inlet and a fluid outlet are in the processing chamber. A washing device adapted to supply a wash liquid to the substrate while the substrate is in the processing chamber. A liquid removal device adapted to dry the substrate when the substrate is being withdrawn from the processing chamber.

### BACKGROUND OF THE INVENTION

Self-assembled monolayers (SAMs) hold great promise for applications in several different areas. For example, one suggested use of a SAM is as a medium for coupling different protein capture agents to a substrate in a protein-capture device. The capture agents can selectively bind proteins (e.g., enzymes) in, for example, a test fluid. Such protein capture devices can be used to perform assays. Additional details regarding the use of SAMs in protein capture devices are in U.S. Pat. No. 6,329,209, entitled “Arrays of Protein Capture Agents and Methods of Use Thereof,” by Peter Wagner et al. This U.S. patent is assigned to the same assignee as the present application and is herein incorporated by reference for all purposes.

FIGS. 1(a) to 1(c) schematically illustrate a conventional process for forming a SAM on a substrate. Referring to FIG. 1(a), a gold coated substrate 201 may be immersed in a bath 205 with a solution comprising linear molecules 203 such as alkanethiol molecules. As shown in FIG. 1(b), after a predetermined amount of time has passed, the alkanethiol molecules adsorb onto and attach to the gold coated substrate 201 through the thiol groups (not shown) in the molecules. As shown in FIG. 1(c), once attached, the ends of the alkanethiol molecules 203 opposite the thiol groups project away from the gold coated substrate 201. The formed SAM 207 resembles a “carpet” of molecules on the surface of the gold coated substrate 201. After the SAM 207 forms on the gold coated substrate 201, the gold coated substrate is removed from the bath 205. The SAM coated substrate is then washed and dried in separate processing apparatuses (not shown).

While conventional methods of forming SAMs are useful, improvements could be made. For example, in the conventional method described above, the throughput is low. Each substrate is separately dipped, washed, and dried in different processing apparatuses. Time is needed to transfer the substrate to these different apparatuses to form the SAMs. If, for example, large numbers of protein-capture devices with SAMs are to be produced, the conventional method would likely be unable to produce large numbers of high-quality SAM coated substrates in an economical manner. Also, in the above-described method, the bath 207 contains a relatively large volume of linear, organic molecules (e.g., alkanethiols). These molecules are more expensive than conventional reagents so that it is desirable to minimize the amount of reagent used. In the bath described above, a relatively large volume of these organic molecules is used to form a SAM, even though only a few of the organic molecules are eventually bound to the substrate. In addition, a bath 207 such as the one shown in FIGS. 1(a) to 1(c) has a relatively large footprint. It would be desirable to reduce the footprint of a substrate processing apparatus. Reducing the footprint reduces the amount of space that is needed in a manufacturing facility. Lastly, the quality of mass-produced SAMs depends on the method by which they are made. Typically, SAMs are deposited, washed, and dried under strictly controlled conditions. When many different apparatuses are used to form a SAM, the likelihood that the controlled conditions may vary increases. This can affect the quality of the SAM and consequently the quality of the final product.

Embodiments of the invention address the above problems and other problems, collectively and individually.

### SUMMARY OF THE INVENTION

Embodiments of the invention are directed to substrate processing apparatuses and methods for processing substrates.

One embodiment of the invention is directed to a substrate processing apparatus for forming an analytical device, the apparatus comprising: a substrate holder for holding a substrate; a processing chamber including an opening for receiving the substrate holder and the substrate; a fluid inlet in the processing chamber; a fluid outlet in the processing chamber; a washing device adapted to supply a wash liquid to the substrate; and a liquid removal device adapted to dry the substrate when the substrate is being withdrawn from the processing chamber. The washing device can wash the substrate when it is in the processing chamber. The washing device can alternatively wash the substrate as it is being pulled out of the processing chamber.

Another embodiment of the invention is directed to a method for forming an analytical device, the method comprising: (a) inserting a substrate holder and a substrate through an opening in a processing chamber; (b) supplying a reagent into the processing chamber and coating the substrate with the reagent to form a coated substrate; and (c) washing the coated substrate with a wash liquid after b); and (d) removing the coated substrate from the processing chamber, and removing the wash liquid from the coated substrate as the substrate is being removed from the processing chamber. The washing device can wash the substrate when it is in the processing chamber. The washing device can alternatively wash the substrate as it is being pulled out of the processing chamber.

These and other embodiments of the invention will be described in further detail below with reference to the Figures and the Detailed Description. It is understood that embodiments of the invention are not limited to the particular examples described therein.

### BRIEF DESCRIPTION OF THE DRAWINGS

FIGS. 1(a) to 1(c) are schematic drawings illustrating a partial process flow for a method for forming a self-assembled monolayer on a gold substrate.

FIG. 2(a) shows a flowchart illustrating a method of processing a substrate using a substrate processing apparatus according to an embodiment of the invention.

FIG. 2(b) is a block diagram of a substrate processing apparatus according to an embodiment of the invention.

FIG. 3 shows a side-view of a substrate processing apparatus according to an embodiment of the invention. Invisible lines show the interior of a processing chamber and a substrate to be processed.

FIG. 4 shows a perspective view of a substrate holder within a processing chamber. Invisible lines illustrate a portion of the substrate holder.

FIG. 5 shows an exploded view of a chamber portion, a substrate holder, and a substrate.

FIG. 6 shows a chamber portion, a substrate holder and a substrate. The substrate and the substrate holder are shown as they would be when the substrate is being processed.

FIG. 7(a) shows a close-up view of a substrate holder according to an embodiment of the invention.

FIG. 7(b) shows teeth on the substrate holder shown in FIG. 7(a).

FIG. 8 shows a graph comparing a number of thickness measurements at different points on different SAM-coated wafers vs. the values of those thicknesses in nanometers.

FIG. 9 shows overlapping sets of FTIR spectra of SAMs produced by a manual process and a process according to embodiment of the invention.

FIG. 10 shows a bar chart of the thickness of a SAM derived from MUA (mercaptoundacanoic acid) as determined by an ellipsometer vs. various trials.

FIG. 11 shows a schematic view of the immobilization of a protein-capture agent on a monolayer-coated substrate via an affinity tag and an adaptor.

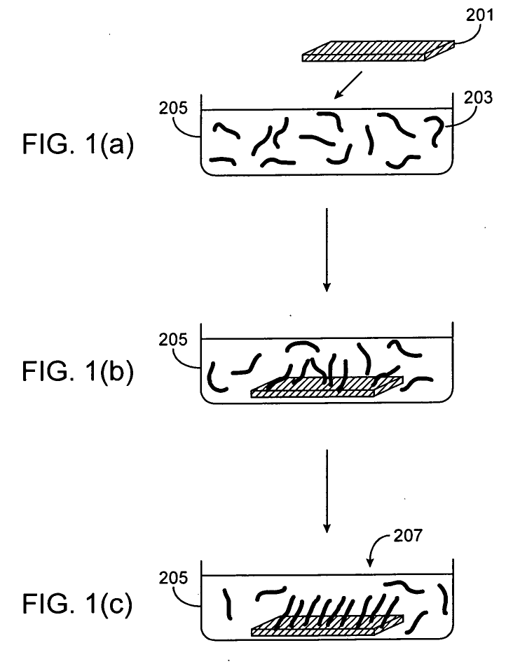

Further details regarding the embodiments shown in the Figures as well as other embodiments are provided below in the Detailed Description.

### DETAILED DESCRIPTION

Embodiments of the invention are directed to substrate processing apparatuses and methods for processing substrates that can eventually be used as analytical devices. The analytical devices can be used in a biological or chemical analysis process. The substrates in the analytical devices may have chemical or biological molecules disposed in an array on the substrate. In some embodiments, there may be no array involved, b) there may be an array on the substrates before the substrates are processed in the substrate processing apparatus and c) there may be an array formed on the substrates after the process step involving the substrate processing apparatus. An array of biological molecules may be used, for example to assay a biological fluid to see if the biological fluid contains a particular biological molecule.

Embodiments of the invention are especially useful for forming SAMs or self-assembled monolayers. A “self-assembled monolayer” is a monolayer, which is created by the spontaneous assembly of molecules. A self-assembled monolayer may be ordered or disordered. In embodiments of the invention, a SAM may be used as an intermediate layer in an analytical device.

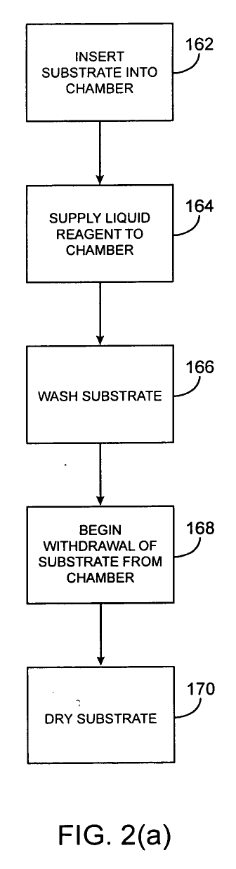

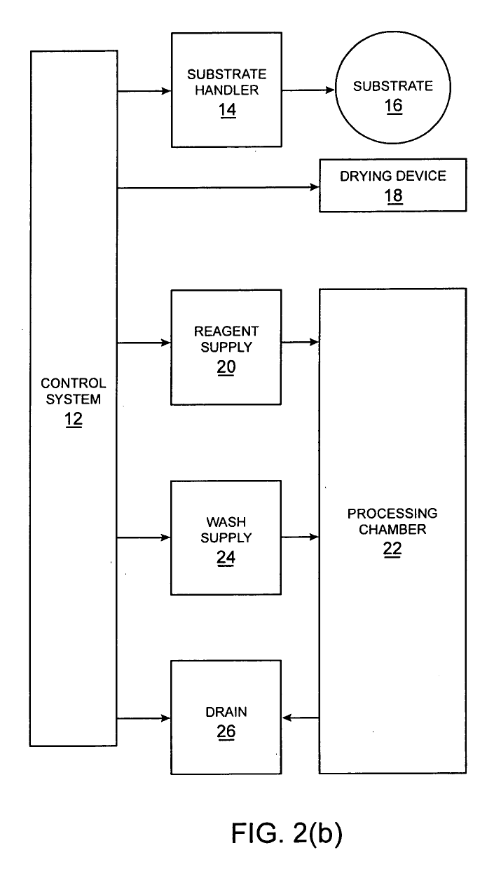

A method according to an embodiment of the invention can be described with respect to FIG. 2(a). Referring to FIG. 2(a), the method includes inserting a substrate holder and a substrate substantially vertically through an opening (e.g., a slit) in a processing chamber (step 162). In some embodiments, the processing chamber is vertically oriented. That is, the vertical dimension of the interior of the processing chamber is greater than the horizontal dimension of the processing chamber.

Any suitable substrate may be processed in embodiments of the invention. The substrate may be coated or uncoated, and can be in any suitable form (e.g., a circular wafer, or a rectangular substrate). For example, the substrate can be a silicon wafer with a gold coating on it. In other embodiments, the substrate may be a precut substrate that was cut from a larger structure such as a larger wafer. Additional examples of suitable substrates that can be processed are provided below.

The processing apparatus may have any suitable number of processing chambers. A typical processing apparatus may have more than two processing chambers, each processing chamber processing one or more substrates. In this way, many substrates can be processed in parallel. For simplicity of illustration, the embodiments described with reference to the Figures include a single processing chamber.

It is desirable to minimize the amount of liquid reagent for a given area. Accordingly, the ratio of the volume of the processing chamber to the surface area to be coated can be small. For example, in some embodiments, each processing chamber may have a volume that is less than about 32 milliliters for coating an area of about 78 cm² or more. In some embodiments, each processing chamber may have a ratio of volume to coated area of less than about 0.4 ml/cm².

Any suitable fluid may be used to process the substrate. For example, liquid reagents may be used to process the substrate. Preferred liquid reagents may comprise linear molecules at least about 5 atoms long. Examples of linear molecules include hexanedecanethiol, mercaptoundecanonoic acid (MUA) and dithiobis(succinimidylundecanoate) (DSU). Other examples of linear molecules include thiols and disulfides. Examples include, e.g., HS—(CH₂)ₙ-(EG)ₓ-Y, [—S—(CH₂)ₙ-(EG)ₓ—Y]₂, and Y-(EG)ₓ-(CH₂)ₙ—S—S—(CH₂)ₙ-(EG)ₓ-Y, where EG is ethylene glycol, n is from about 2 to about 16, x is from 0 to about 44, and Y is CH₃, OH, COOH, MI (maleimide), NHS (N-hydroxyl succinimide), NTA (nitrilotriacetic acid), mercaptoundecane, dodecyl disulfide, 11-mercaptoundecanoic acid, 11-mercaptoundecyl trifluoroacetate, or NTA- or MI- or NHS-terminated tetra(ethylene glycol) undecyldisulfide. Other suitable reagents may include branched molecules, polymers such as dextrane (both functionalized and non-functionalized), copolymers such as PLL-PEG (poly-L-lysine-polyethylene glycol) (both functionalized and non-functionalized), silanes (both functionalized and non-functionalized), peptides, proteins, and other biomolecules. Other examples include (EtO)₃—(CH₂)ₙ-(EG)ₓ—Y and (MeO)₃₋Si—(CH₂)ₙ-(EG)ₓ-Y, where EtO is ethylene oxide, MeO is methylene oxide, n=2−20, x is defined above, and Y is defined above. Y could also be 3-aminopropyl triethoxysilane, 3-mercaptopropyl trimethoxysilane, 11-azidoundecyl triethoxysilane, and 11-NHS-tetraethylene glycol-undecyl triethoxysilane (or derivative thereof). Molecules like those above may be present in an appropriate solvent (e.g., ethanol or chloroform) and may be used to form a SAM. The solvents may be aqueous, buffered or non-buffered, or even gaseous.

After the substrate holder and the substrate are within the processing chamber, a liquid reagent is introduced into the processing chamber through at least one liquid inlet that is, e.g., above the substrate (step 164). The at least one liquid inlet can be at any suitable location in the apparatus. During processing, the liquid reagent fills the processing chamber.

As it fills the processing chamber, it starts coating the substrate with the liquid reagent to form a coated substrate. The substrate may be totally or partially immersed in the liquid reagent. In some embodiments, the liquid reagent may be optionally heated to facilitate a desired reaction between the molecules in the liquid reagent and the substrate or a layer on the substrate. In an alternative embodiment, the liquid reagent may be introduced to the processing chamber before the substrate is inserted into it.

After coating the substrate, the coated substrate is washed while it is within the processing chamber (step 166). A washing device in communication with a wash supply can supply a washing liquid to the interior of the processing chamber. In other embodiments, the washing device can supply a washing liquid to the substrate as the substrate is being pulled out of the substrate.

The substrate can be washed with a clean solvent after the liquid reagent reacts with the substrate surface. This can be done to avoid the re-depositing or crystallization of the previous liquid reagent onto the substrate surface. Molecular deposition, for example, can lead to an inhomogeneous coating on a substrate, or even to the destruction of a deposited layer (by crystallization). Molecular deposition happens when substrate surfaces are removed from the liquid reagent, and the liquid drops that are left on the substrate evaporate and leave behind non-volatile contaminants or molecules on the surface of the substrate.

Any suitable washing liquid may be used. Exemplary washing liquids include water and alcohols such as ethanol. The washing liquid may be a polar or a non-polar liquid. The coated substrate can be washed once with a washing liquid or more than once with the same or different washing liquids.

After washing, the coated substrate is then removed from the processing chamber (step 168). As it is being removed from the processing chamber, the coated substrate is dried (step 170). A drying device such as an air knife above the opening to the processing chamber can dry the coated substrate as it is being withdrawn from the processing chamber. Any suitable drying gas may be used including inert gases such as nitrogen or argon, or even air. Although drying is the preferred way to remove the washing liquid from the substrate, other liquid removal processes such as squeegeeing or vacuum drying would also be used. Also, several drying stages may be connected in series to achieve a better drying effect.

The subsequent removal of liquid on the surfaces of the substrate after the washing step is desirable to make sure that areas of the substrate are not exposed to the washing liquid longer than other areas. The uneven exposure of liquids to the substrate can make the formed coating inhomogeneous. Liquid removal also reduces the likelihood of cross-contamination from one processing chamber to the next. Good and complete liquid removal makes it possible for a substrate to be processed in a series of reactions using incompatible solvents (e.g., water based solvents and organic solvents).

After the washing liquid is removed from the substrate, the coated substrate may be optionally placed in a holding chamber. The holding chamber may include an inert gas such as argon. The holding chamber may hold the coated substrate while other substrates are being processed in the processing chamber. After a batch of substrates is processed, the batch of substrates may then be removed. Another batch of substrates may then be processed in a similar manner. In yet other embodiments, it is possible to deposit many layers on a single substrate by having, first, second, third, etc. processing chambers in the system that can deposit successive layers on top of each other. The first, second, third, etc. processing chambers can have the same or different configurations as the processing chambers described herein.

If desired, the substrates can then be further processed after they are coated. In some embodiments, an array of biological or chemical molecules is formed on the coated substrate. For example, if a protein-capture device is to be formed, after forming a SAM coated substrate, various protein capture agents, adaptors, affinity agents, etc. could then be coupled (directly or indirectly) to molecules in the SAM. Exemplary protein capture devices are described in further detail below. As will be described in further detail below, array forming apparatuses such as ink jet printers or micro-stamping can be used to deliver, for example, capture agents to specific regions of the SAM to form a protein-capture device. The array forming apparatus and the substrate processing apparatus may form a system used to create analytical devices.

Embodiments of the invention have a number of advantages. First, in embodiments of the invention, a single processing apparatus may be used to coat, wash, and dry a substrate, while minimizing the movement of the substrate. This provides for greater processing throughput in comparison to conventional processing apparatuses, because three processing steps can be performed with a single processing apparatus. This also reduces potential processing variations since processing parameters can be set for a single apparatus instead of three different processing apparatuses. Second, embodiments of the invention can use less reagent to form a coating then conventional methods. As noted above, in some embodiments, the volume of the processing chamber may be close to the volume of the substrate being processed. Third, because the processing chambers in embodiments of the invention can be vertically oriented, the apparatuses using those processing chambers have a small footprint. Fourth, because of the configuration of the components of the apparatus in embodiments of the invention, contamination on the surface of the substrate is minimized. In embodiments of the invention, a wash liquid is virgin and clean when coming into contact with the substrate in the processing chamber. The washing liquid does not come into contact with surface previously exposed to reagents before contacting the substrate. It is understood that some embodiments of the invention may have some of the above noted advantages while other embodiments of the invention may have all of the above noted advantages.

A schematic block diagram of the functional components of an apparatus according to an embodiment of the invention is shown in FIG. 2(b). FIG. 2(b) shows a control system 12 in operative communication with a substrate handler 14, a drying device (or other liquid removal device) 18, a reagent supply 20, a wash supply 24, and a drain 26. The reagent supply 20, the wash supply 24, and the drain 26 are in communication with the processing chamber 22.

The control system 12 can control the substrate handler 14, which inserts the substrate 16 into a processing chamber 22 or removes the substrate 16 from it. The processing chamber 22 can be one processing chamber within a bank of processing chambers and the control system 12 can control the processing in each processing chamber. The control system 12 can also control the drying device 18 so that the substrate 18 is properly dried as it is being removed from the processing chamber 22.

The control system 12 can also regulate the liquids flowing into the processing chamber 22 and out of the processing chamber 22. Various processing parameters (not shown) can be adjusted to regulate the flow of liquids throughout the system. For example, the control system 12 can control the flow rates of one or more reagents from the reagent supply 20 into the processing chamber 22. The control system 12 can also control the flow rate of a washing liquid from the wash supply 24 into the processing chamber 22. It can also control the flow rate of liquid passing out of the processing chamber 22 (i.e., liquid flowing in the drain 26 flowing downstream of the substrate 16).

Using the control system, embodiments of the invention may be fully or partially automated. By fully or partially automating the apparatus according to embodiments of the invention, layers can be formed on substrates more quickly and with less variation. The control system can be programmed by one of ordinary skill in the art so that substrates can be processed in an intended manner.

An illustrative method of using the system shown in FIG. 2(b) can be described. In the illustrative method, the control system 12 causes the substrate handler 14 to engage a substrate holder (not shown). After the substrate handler 14 engages the substrate holder, the substrate handle 14 moves the substrate 16 past the drying device 18 and inserts the substrate 16 into the processing chamber 22. Thus, the substrate handler 14 can manipulate the substrate 16 indirectly through the substrate holder. When the substrate 16 is inserted into the processing chamber 22, it is generally vertically oriented. At this point, the drying device 18 is not turned on.

Once the substrate 16 is in the processing chamber 22, the control system 12 causes the reagent supply 20 to supply a liquid reagent into the interior of the processing chamber 22. The liquid reagent may comprise a precursor for forming a SAM on the substrate. For example, the liquid reagent may include alkanethiols. The liquid reagent quickly fills the processing chamber 22 and contacts the substrate 16. After the processing chamber 22 is filled with the liquid reagent, the substrate 16 is immersed in the liquid reagent. After the substrate 16 is in contact with the liquid reagent for an appropriate amount of time (the time may vary depending on the particular type of layer being formed), the control system 12 causes the liquid reagent to pass from the processing chamber 22 and into the drain 26.

After the liquid reagent drains from the processing chamber 22, the control system 12 causes the wash supply 24 to supply a wash liquid into the processing chamber 22 to wash the substrate 16. The wash liquid may comprise water. The substrate 16 can be washed any suitable number of times.

After the substrate 16 is washed, the control system 12 causes the substrate handler 14 to remove the substrate 16 from the processing chamber 22. As the substrate 16 is being removed from the processing chamber 22, the control system causes the drying device 18 to dry the substrate 16.

Before or after the substrate 12 is removed from the processing chamber 22, the control system 12 causes the wash liquid in the processing chamber 22 to pass from the processing chamber 22 into the drain 26, and downstream to a waste reservoir (not shown).

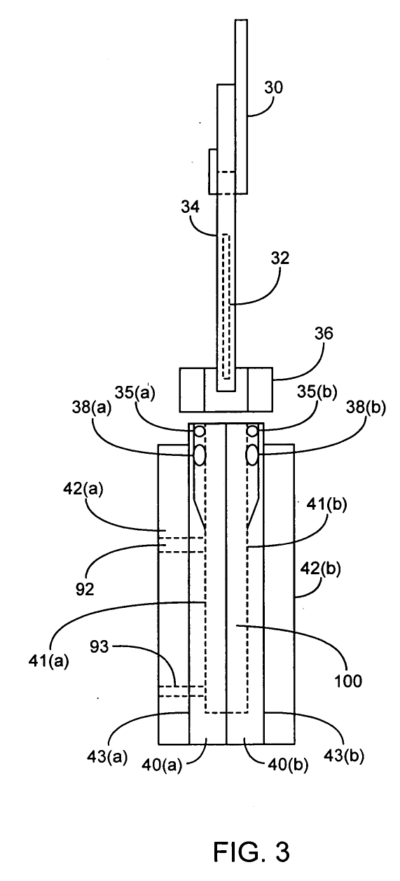

FIG. 3 shows a side view of some parts of a processing apparatus according to an embodiment of the invention. Referring to FIG. 3, a processing chamber 100 is formed using two chamber portions 40(a), 40(b). Each chamber portion 40(a), 40(b) may be separated from each other and each chamber portion 40(a), 40(b) may include an inner surface 41(a), 41(b) forming a recess in its respective chamber portion 40(a), 40(b). The outer surfaces 43(a), 43(b) of the chamber portions 40(a), 40(b) are opposite to the respective inner surfaces 41(a), 41(b). When the two inner surfaces 41(a), 41(b) of the chamber portions 40(a), 40(b) face each other, they define the interior of the processing chamber 100.

As shown in FIG. 3, the processing chamber 100 is vertically oriented and cooperatively structured to receive a substrate and/or a substrate holder holding the substrate. Each chamber portion 40(a), 40(b) can include a chemically inert material such as polytetrafluoroethylene (i.e., Teflon™). Other materials such as metals may also be used to form the chamber portions 40(a), 40(b).

In the illustrated embodiment, a pair of pressure plates 42(a), 42(b) sandwich the chamber portions 40(a), 40(b). In some embodiments, the pressure plates 42(a), 42(b) can be two plates of aluminum. The pressure plates 42(a), 42(b) are biased to apply pressure inwardly toward each other so that they apply pressure evenly to the outer surfaces 43(a), 43(b) of the chamber portions 41(a), 41(b) so that they are held together tightly.

Pressure plates are especially useful if the chamber portions 41(a), 41(b) are made of a soft material such as polytetrafluoroethylene. If uneven pressure is applied to soft chamber portions 41(a), 41(b), the soft chamber portions 41(a), 41(b) could deform in an uneven manner. However, in other embodiments of the invention, the pressure plates 42(a), 42(b) could be replaced with screws, bolts, or other securing means (e.g., adhesives). In embodiments of the invention, any suitable securing mechanism may be used to secure the two chamber portions 41(a), 41(b) together.

In other embodiments, it is not necessary to have two chamber portions 41(a), 41(b) forming the processing chamber 100. For example, a single block of material may be machined or molded to form the processing chamber 100. In this case, the processing chamber 100 would be formed with a single integral piece of material, rather than separate portions.

In some embodiments, it is desirable to have chamber portions 40(a), 40(b) that can easily separate from each other. For example, in the example shown in FIG. 3, the processing chamber 100 has a relatively small volume. Because of the relatively small volume, it is difficult to clean the inner surfaces 41(a), 41(b) forming the processing chamber 100. If the chamber portions 40(a), 40(b) can be easily separated from each other, they can be more easily replaced or cleaned than when the processing chamber 100 is formed from a single, integral material.

Liquid inlets 38(a), 38(b) may be formed in the chamber portions 40(a), 40(b). In this example, the liquid inlets 38(a), 38(b) are proximate the upper portion of the processing chamber 100 and are formed in the sides of the chamber portions 40(a), 40(b). Each liquid inlet 38(a), 38(b) can be used to supply a liquid reagent to the processing chamber 100. In this example, each liquid inlet 38(a), 38(b) is disposed above the region where the substrate is eventually processed in the processing chamber 100.

A wash liquid may be supplied through wash lines 35(a), 35(b). The wash liquid may comprise, for example, water. The wash liquid can be used to remove unbound liquid reagent molecules from the substrate, therefore leaving only the bound molecules on the substrate. Each wash line 35(a), 35(b) can comprise a perforated tube. Other washing devices could be used instead of wash lines. For example, a showerhead could be used in place of the wash lines 35(a), 35(b).

A third liquid inlet 92 passes through one chamber portion 40(a) and an adjacent pressure plate 42(a). In some embodiments, a liquid reagent may be introduced to the processing chamber 100 through this third liquid inlet 92 instead of or in addition to the first and second liquid inlets 38(a), 38(b). This third liquid inlet 92 can pass through both the inner surface 41(a) and the outer surface 43(a) of the chamber portion 40(a) and can be centered above the substrate 32 when it is in the processing chamber 100. This can provide for a more even distribution of the liquid reagent over the surfaces of the substrate 32.

A liquid outlet 93 is proximate the lower portion of the processing chamber 100. The liquid outlet 93 can be used to drain liquid reagents or wash liquids from the processing chamber 100. Generally, the processing region of the processing chamber is between the liquid inlet 92 and the liquid outlet 93. The surface of the substrate 32 to be coated resides in this processing region. The inlet 92 could also be in the bottom of the chamber.

A substrate handler 30, a substrate holder 34, and a substrate 32 are above the processing chamber 100. The substrate holder 34 holds the substrate 32 (shown by invisible lines) as it is being transported into and out of the chamber 44. The substrate handler 30 engages the substrate holder and manipulates the substrate 32 using the substrate holder 34. The substrate holder 34 can be made of metal or an inorganic material such as quartz.

A drying device 36 is between the substrate handler 30 and the processing chamber 44. In preferred embodiments, the drying device 36 is an air knife. Such air knives are commercially available from Exair and Paxton. The drying device 36 may supply a drying gas such as air inwardly to one or both sides of the substrate 32 to dry it as it is being withdrawn from the processing chamber 44. The drying gas could be air, nitrogen, or an inert gas such as argon.

Although one processing chamber is illustrated in FIG. 3, it is understood that in embodiments of the invention, there may be many such processing chambers and these processing chambers may form a bank of processing chambers. In embodiments of the invention, the apparatus has at least 2, or 3 chambers in a side-by-side relationship. Many substrates can be processed efficiently in parallel or serially using the bank of processing chambers. Because each processing chamber is oriented vertically, the bank of processing chambers would have a small footprint in a processing facility.

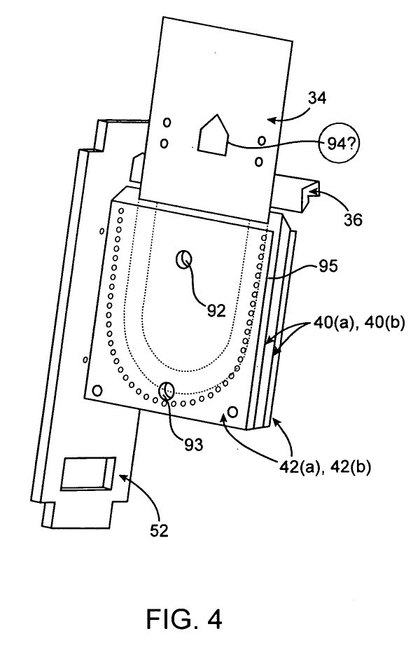

FIG. 4 shows a perspective view another embodiment of the invention. In this embodiment, the chamber portions 40(a), 40(b) and the pressure plates 42(a), 42(b) are attached to a side mounting structure 52. The mounting structure 52 could be a metal bracket. The drying device 36 may also be mounted to the mounting structure 52 (only one drying device is shown for simplicity of illustration). The mounting structure 52 can, in turn, be mounted to a wall or other vertical structure.

A set of securing members 95 can mechanically couple the pressure plates 42(a), 42(b) and the chamber portions 40(a), 40(b) together. In FIG. 4, the securing members 95 are arranged in a U-shaped configuration to form a tight seal in the region defining the interior of the processing chamber. The securing members may comprise, for example, nuts and bolts.

In FIG. 4, the liquid inlet 92 and the liquid outlet 93 that pass through the major faces of the chamber portion 40(a) are more clearly shown. Also, a central hole 99 in the substrate holder 34 is also shown. The central hole 99 has an apex and is in the form of a pentagon. In embodiments of the invention, the substrate handler (not shown in FIG. 4) that is used to manipulate the substrate can include a hook or other coupling structure. The coupling structure can be inserted into the central hole 99 of the substrate holder 34 to engage the substrate handler with the substrate holder 34. After the substrate handler engages the substrate holder 34, the coupling structure in the substrate handler resides at the apex of the central hole 99 and automatically aligns the substrate holder 34 and the substrate (not shown).

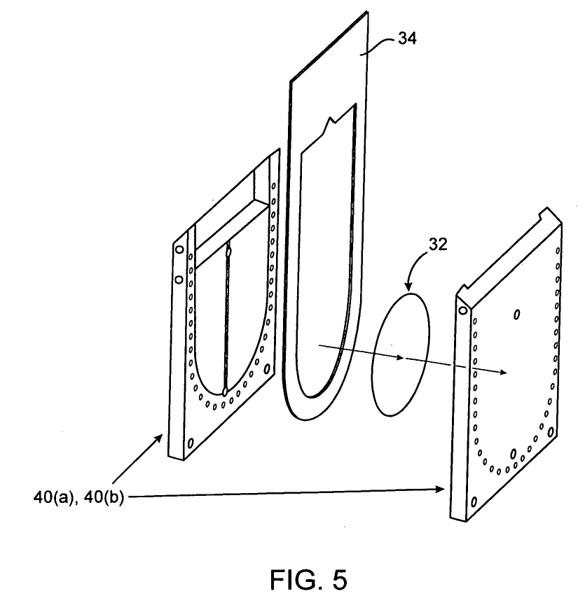

FIG. 5 shows an exploded view of some of the chamber portions 40(a), 40(b), the substrate holder 34, and the substrate 32. As shown in FIG. 5, each chamber portion 40(a), 40(b) includes a plurality of holes. Each plurality of holes is in the form of a U-shape. When the holes in each plurality of holes are aligned with each other, securing members such as a number of bolts may pass through the aligned holes to secure the chamber portions 40(a), 40(b) together.

In the embodiment shown in FIG. 5, the substrate holder 34 is different than the substrate holder shown in FIG. 4. Unlike the substrate holder in FIG. 4, the substrate holder 34 shown in FIG. 5 does not have a central hole, but has a triangular inner edge with an apex. As shown in FIG. 5, the substrate 32 would be coupled to the U-shaped portion of the substrate holder 34 and would be situated in the bottom region of the processing chamber formed by the two chamber portions 40(a), 40(b).

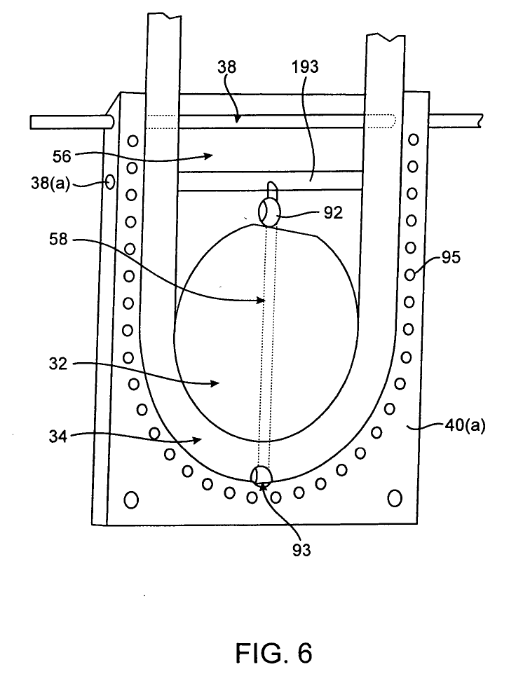

FIG. 6 shows one chamber portion 40(a) with a substrate 32 placed in a recess formed by the inner surface of the chamber portion 40(a). A substrate holder 34 holds the substrate 32 by its edges when the substrate 32 is processed. The substrate holder 34 can have a V-groove along its inner edge to hold the substrate 32. As shown in FIG. 6, the chamber bottom and sides are cooperatively configured with the geometry of the substrate holder and the substrate to minimize the volume of the processing chamber.

A wash line 35(a) may be in communication with a wash supply (not shown) and may be in the form of a tube with holes in it. The wash line 35(a) is used to shower the substrate and to provide for even liquid dispensing from both sides of the substrate. The wash line 35(a) may pass through the sides of the chamber portion 40(a). In some embodiments, the wash line 35(a) may comprise a perforated Teflon tube.

Both the wash line 35(a) and a liquid inlet 38(a) may be disposed above a ledge 193 formed in the chamber portion 40(a). The substrate 32 is below the ledge 193, the wash line 35(a), and the liquid inlets 38(a), 92 when the substrate 32 is being processed. The ledge 193 provides a wider area near the top of the processing chamber to allow for spacious showering and draining.

A vertical channel 58 is formed (partially shown by invisible lines) in the chamber portion 40(a) and passes from the liquid inlet 92 to the liquid outlet 93. Liquid reagent can flow down the vertical channel 58 and can allow the processing chamber to drain faster. Fast draining is desirable for high flux washing when forming, for example, a SAM coated substrate.

In this example, the chamber portion 40(a) includes a liquid inlet 38(a) at a side of the chamber portion 48(a) and another liquid inlet 92 passing through both major surfaces of the chamber portion 48(a). Either liquid inlet 38(a), 92 may serve as an entry port for the one or more liquid reagents that are introduced to the process chamber and that are used to process the substrate 16. When a liquid reagent is introduced into the processing chamber through the liquid inlet 38(a), the liquid reagent can flow along the ledge 193 so that it is evenly distributed above the substrate 32.

he liquid reagents may be introduced though the liquid inlets 38(a), 92 automatically or manually. For example, in some embodiments, the liquid reagents may be manually pipetted through either or both of the liquid inlets 38(a), 92. In other embodiments, liquid reagents may be automatically introduced to the liquid inlets 38(a), 92 by automatically opening and closing valves in lines upstream of the liquid inlets 38(a), 92.

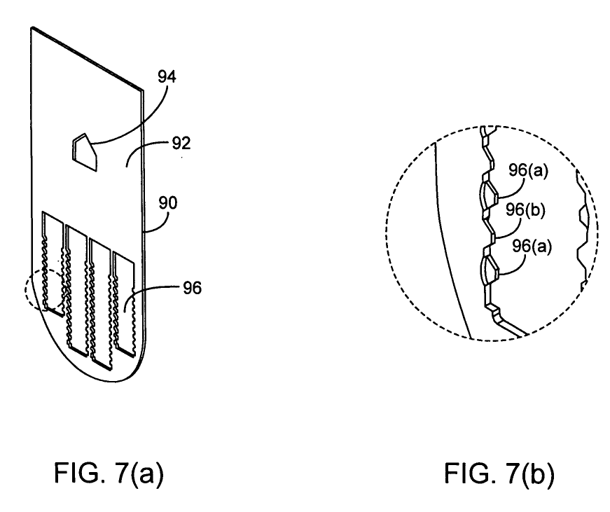

FIG. 7(a) shows details of a substrate holder 90 according to an embodiment of the invention. The substrate holder 90 has four elongated open regions 96 defined by inner edges with teeth. Each open region 96 is used to hold a rectangular substrate (not shown). This is unlike the previously described substrate holders, which were adapted to hold circular substrates. As shown in FIG. 7(a), the substrate holders according to embodiments of the invention may hold one or more than one substrate. The substrate holder 90 also includes a hole 94 with an apex for receiving a coupling element (e.g., a hook) in a substrate handler (not shown). The bottom edge of the substrate holder is curved and U-shaped in this embodiment.

FIG. 7(b) shows the details of the teeth bordering an open region. As shown in FIG. 7(b), a rectangular substrate (not shown) may be held between alternating teeth 96(a), 96(b) to secure it within the open region.

The rectangular substrates may be pre-cut from a larger substrate such as a silicon wafer. When manufacturing biological analytical chips, the dicing or cutting of the wafer after forming the appropriate layers on a substrate may contaminate the chips. Accordingly, in embodiments of the invention, the substrates may be pre-cut substrates that are inserted into the processing chamber of the substrate processing apparatus.

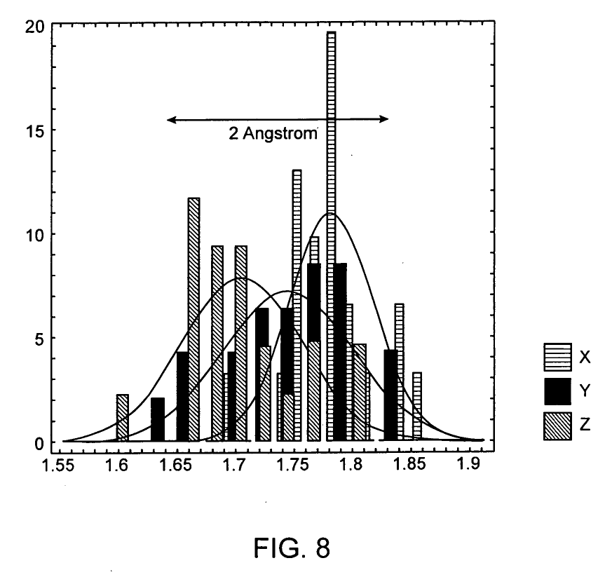

Embodiments of the invention can be used to produce high-quality, uniform coatings. This is illustrated in FIGS. 8-10.

FIG. 8 shows a graph, which illustrates the repeatability of embodiments of the invention, both on a single wafer and between different wafers. In this example, a gold coated wafer was coated with hexadecanethiol. This wafer was then washed and dried using the above described processing apparatus to form a SAM coated wafer. Two other wafers were prepared in a similar manner. The preparation for these three wafers was identical. The sequence of events regarding the metrology (e.g., the procedure for characterizing a SAM) was identical for all wafers.

In the graph shown in FIG. 8, the x-axis shows the thickness of a SAM derived from hexadecanethiol in nanometers. The y-axis shows the number of measurements (normalized) obtained at a given thickness. The thickness measurements were obtained using an ellipsometer.

For each SAM-coated wafer, multiple measurements of the thickness of each SAM were made at different locations on the wafer. In FIG. 8, the same bar pattern designates measurements on a particular wafer. Three bell curves correspond to the respective sets of thickness measurements of SAMs on different wafers. As shown in FIG. 8, the central points of the three bell curves are within a two angstrom window. The average for the bars labeled X is 1.78 (nanometers) (standard deviation=0.04), the average for the bars labeled Y is 1.74 (standard deviation=0.06), and the average for the bars labeled Z is 1.71 (standard deviation=0.05). The graph shows that the average thicknesses of three SAMs on three different wafers were very close using embodiments of the invention. As shown by the width of each bell curve, the thickness variation within each SAM layer is also low, thus indicating that SAMs of uniform thickness can be produced using embodiments of the invention.

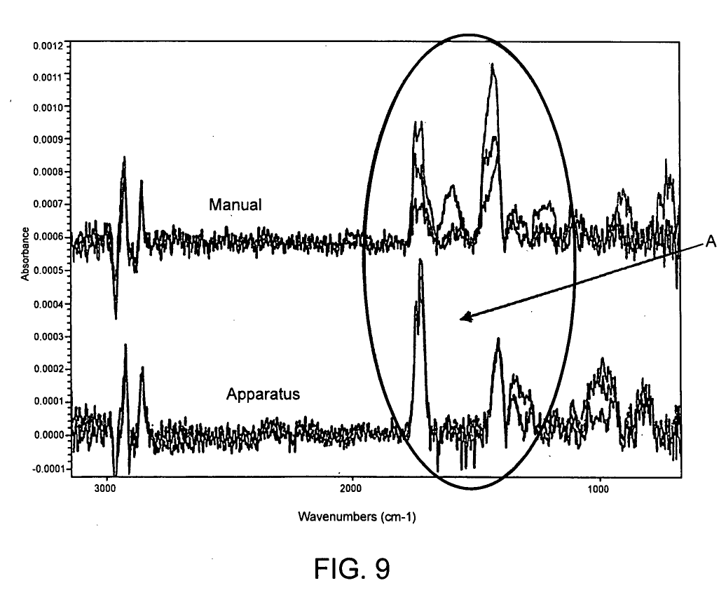

FIG. 9 shows FTIR (Fourier Transform Infrared) spectra for three SAM layers produced using a manual process and three SAM layers produced using an apparatus according to an embodiment of the invention. In the manual process, a wafer was manually dipped in a Petri dish containing SAM precursor molecules. The wafer was then manually rinsed, and then dried.

Changes in the FTIR spectra from SAM to SAM across different wafers can signal a change in the chemical compositions in the SAMs. The FTIR data shows that there was variation in the spectra associated with the manual preparations. In the region “A”, the three spectra have peaks that do not overlap. This indicates that the SAMs prepared using manual processes had different compositions on different substrates. In comparison, the three spectra corresponding to the system embodiment overlap. This shows that the chemical composition of the SAMs across three wafers did not vary when SAMs were produced using embodiments of the invention.

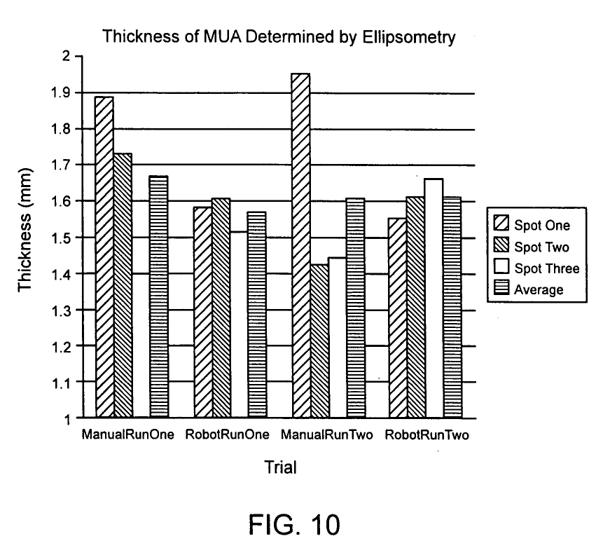

FIG. 10 shows a graph of thickness (nanometers) of a SAM derived from MUA (mercaptoundecanonic acid) vs. trial (manual or robot runs). The thicknesses of the SAMs were determined using an ellipsometer. As shown in FIG. 10, three spots per wafer were measured for thickness and an average thickness was calculated for each SAM on each wafer. As shown in FIG. 10, the SAMs produced by the robot runs (i.e., embodiments of the invention) had thickness measurements between about 1.5 to 1.7 nm, both within each SAM on each wafer and between different SAMs on different wafers. In comparison, in the manual runs, the thickness of the SAMs varied widely both within each SAM and between SAMs on different wafers. Thus, in comparison to manual preparation processes, SAMs with more consistent thicknesses can be achieved using embodiments of the invention.

In some embodiments, after forming a SAM-coated substrate, the SAM-coated substrate may then be further processed to form a protein-capture device. For example, in some embodiments, after forming a SAM-coated substrate, discrete regions of different protein capture agents can be formed on the SAM layer to form a protein capture device. As will be explained in further detail below, the discrete regions may form an array.

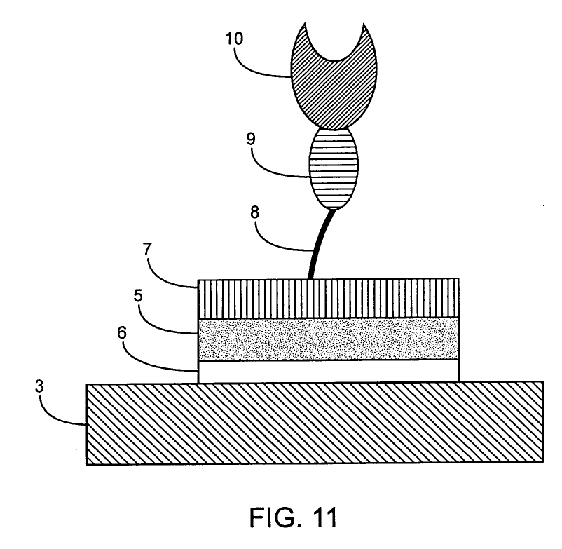

FIG. 11 shows an example of a portion of such an example of a protein capture device. As noted above, additional details regarding the use of SAMs in protein capture devices are in U.S. Pat. No. 6,329,209, which is assigned to the same assignee as the present application and which is herein incorporated by reference for all purposes.

FIG. 11 shows a schematic cross-section of a region of a capture device. Only one region is shown for simplicity of illustration, and elements in FIG. 11 are enlarged for clarity of illustration. The region comprises a protein-capture agent 10 immobilized on a monolayer 7 via both an affinity tag 8 and an adaptor 9. The affinity tag 8 and/or the adaptor 9 are optional. For example, a protein-capture agent 10 could be coupled directly to a molecule in the monolayer 7 in capture devices. Referring again to FIG. 11, the monolayer 7 rests on a coating 5. An interlayer 6 is used between the coating 5 and the substrate 3. For purposes of illustration, only one protein capture agent 10 is coupled to the monolayer 7.

The substrate 3 may be either organic or inorganic, or biological or non-biological. Numerous materials are suitable for use as a substrate in the array embodiment of the invention. For instance, the substrate of the invention array can comprise a material selected from a group consisting of silicon, silica, quartz, glass, carbon, alumina, titania, tantalum oxide, germanium, silicon nitride, zeolites, and gallium arsenide. Many metals such as gold, platinum, aluminum, copper, titanium, and their alloys may also be used.

The coating 5 may comprise, for example, a metal. Possible metal films include aluminum, gold, silver, chromium, titanium, tantalum, nickel, stainless steel, zinc, lead, iron, copper, magnesium, manganese, cadmium, tungsten, cobalt, and alloys thereof. In a preferred embodiment, the metal film is from about 50 nm to about 500 nm in thickness. The coating 5 may serve as a point of attachment for the molecules in the SAM.

The interlayer 6 may be used as an adhesion layer that bonds the coating 5 and the substrate 3. The interlayer 6 may comprise any suitable material and may have any suitable thickness. Examples of interlayer materials include titanium and chromium.

As shown in FIG. 11, the interlayer 6 and the coating 5 can be patterned or deposited on the substrate 3 by methods known to those of ordinary skill in the art (e.g., electroplating, vapor deposition, etc.). Then, this combination can be processed in the above-described processing apparatus to form a patterned SAM on the coating 5. If, for example, the coating comprises a pattern of gold and the liquid reagent comprises alkanethiol molecules, then the thiol groups in the molecules will bind to the gold, but not the underlying substrate 3. In this way, a patterned SAM layer can be formed. Thus, substrates with or without patterned or unpatterned layers can be processed using embodiments of the invention.

The monolayer 7 may be a SAM and may comprise or be derived from linear molecules including linear alkanethiol molecules (e.g., hexanedecanethiol), mercaptoundecanonoic acid (MUA) and dithiobis(succinimidylundecanoate) (DSU). Typically such linear molecules are hydrocarbon molecules with a linker group at one or both ends so that the ends of the molecules can be bound to a surface, while the other ends extend away from the surface. Other SAMS may be formed from the reagents that are described above.

The protein capture agent 10 may comprise any biological molecule that can capture a protein. Examples of protein capture agents include antibody moieties, proteins, polypeptides, etc. On the substrate, different regions may comprise different groups of protein capture agents.

Since the protein-capture agents of at least some of the different regions are different from each other, different solutions, each containing a different, preferably, affinity-tagged protein-capture agent, can be delivered to their individual regions or on a SAM. Solutions of protein-capture agents may be transferred to the appropriate regions via arrayers which are well-known in the art and even commercially available. For instance, microcapillary-based dispensing systems may be used. These dispensing systems are preferably automated and computer-aided. The use of other microprinting techniques for transferring solutions containing the protein-capture agents to the agent-reactive regions is also possible. Ink-jet printer heads may also optionally be used for precise delivery of the protein-capture agents to the agent-reactive regions. Techniques useful for depositing the protein-capture agents on the regions of a monolayer may be found, for example, in U.S. Pat. No. 5,731,152 (stamping apparatus), U.S. Pat. No. 5,807,522 (capillary dispensing device), U.S. Pat. No. 5,837,860 (ink-jet printing technique, Hamilton 2200 robotic pipetting delivery system), and U.S. Pat. No. 5,843,767 (ink-jet printing technique, Hamilton 2200 robotic pipetting delivery system), all of which are incorporated by reference herein. Adaptors and affinity tags could also be deposited on a monolayer using techniques such as these.

The affinity tag 8 is a functional moiety capable of directly or indirectly immobilizing a protein-capture agent onto an exposed functionality of the monolayer. Preferably, the affinity tag enables the site-specific immobilization and thus enhances orientation of the protein-capture agent onto the monolayer. In some cases, the affinity tag may be a simple chemical functional group. Other possibilities include amino acids, poly(amino acid) tags, or full-length proteins. Still other possibilities include carbohydrates and nucleic acids.

The adaptor 9 can be any entity that links an affinity tag to the protein-capture agent. The adaptor may be, but need not necessarily be, a discrete molecule that is noncovalently attached to both the affinity tag and the protein-capture agent. The adaptor can instead be covalently attached to the affinity tag or the protein-capture agent or both (via chemical conjugation or as a fusion protein, for instance). Proteins such as full-length proteins, polypeptides, or peptides are typical adaptors. Other possible adaptors include carbohydrates or nucleic acids.

Protein-capture devices can be used in a variety of applications including proteomics and diagnostics. Such applications typically involve the delivery of the sample containing the proteins to be analyzed to an array of regions with different protein capture agents. For example, the sample may be a cellular extract or a body fluid comprising proteins. After the proteins of the sample have been allowed to interact with and become immobilized on the regions of the array comprising protein-capture agents with the appropriate biological specificity, the presence and/or amount of protein bound at each region is then determined.

An illustrative method comprises delivering the sample to an array of spatially distinct regions including different protein-capture agents under conditions suitable for protein binding. Each of the proteins being assayed is a binding partner of the protein-capture agent of at least one region on the array. Next, the array is optionally washed to remove unbound or nonspecifically bound components of the sample from the array. After washing, the presence or amount of protein bound to each region is detected, directly or indirectly with appropriate detection equipment.

### EXAMPLE 1

A 4 inch round silicon (100) substrate was obtained. The silicon substrate had a 50 angstrom titanium layer and a 1000 angstrom gold layer on it. The coated substrate was inserted into a processing chamber like the one described with reference to FIG. 3. A reagent liquid comprising 1 mM (millimolar) asymmetric MUA in ETOH was supplied to the processing chamber and the coated substrate was immersed in the reagent liquid. The coated substrate incubated in the reagent liquid for about 17 hours to form an MUA coated substrate. The reagent liquid was drained from the processing chamber. The processing chamber was filled with ETOH and dumped. This was repeated twice. Then, the processing chamber was filled with water and then drained. After the draining, the MUA coated substrate was curtain rinsed with water. The MUA coated substrate was then removed from the processing chamber. As it was being removed, it was dried using a drying knife using nitrogen as a drying gas. A dried, MUA coated substrate was then obtained. The MUA layer had a uniform thickness.

### EXAMPLE 2

A 4 inch round silicon (100) substrate was obtained. The silicon substrate had a 50 angstrom titanium layer and a 1000 angstrom gold layer on it. The coated substrate was inserted into a processing chamber like the one described with reference to FIG. 3. A reagent liquid comprising 1 mM DSU in chloroform was supplied to the processing chamber and the coated substrate was immersed in the reagent liquid. The coated substrate was incubated in the reagent liquid for about 1 hour to form a DSU coated substrate. The reagent liquid was drained from the processing chamber. The DSU coated substrate was then curtain rinsed with chloroform three times. After curtain rinsing, the DSU coated substrate was then removed from the processing chamber. As it was being removed, it was dried using a drying knife using nitrogen as a drying gas. A dried, DSU coated substrate was then obtained. The thickness of the DSU layer was uniform.

The terms and expressions which have been employed herein are used as terms of description and not of limitation, and there is no intention in the use of such terms and expressions of excluding equivalents of the features shown and described, or portions thereof, it being recognized that various modifications are possible within the scope of the invention claimed. Moreover, any one or more features of any embodiment of the invention may be combined with any one or more other features of any other embodiment of the invention, without departing from the scope of the invention. For example, any of the features described with reference to FIG. 11 can be combined with any feature described with reference to any other Figure in embodiments of the invention.

All publications, patents, and patent applications mentioned above are herein incorporated by reference in their entirety for all purposes.

What is claimed is:

1. A substrate processing apparatus for forming an analytical device, the apparatus comprising:
a substrate holder for holding a substrate;
a processing chamber including an opening for receiving the substrate holder and the substrate;
a fluid inlet in the processing chamber;
a fluid outlet in the processing chamber;
a washing device adapted to supply a wash liquid to the substrate; and
a liquid removal device adapted to remove liquid from the substrate when the substrate is being withdrawn from the processing chamber.

2. The substrate processing apparatus of claim 1 wherein the processing chamber is formed by two chamber portions having recesses.

3. The substrate processing apparatus of claim 1 wherein the processing chamber is formed by two chamber portions having recesses, and wherein the substrate processing apparatus further comprises:
a pair of plates on opposite sides of the two chamber portions, wherein the pair of plates apply pressure to the opposite sides of the two chamber portions.

4. The substrate processing apparatus of claim 1 further comprising:
a control system adapted to control the flow of fluid supplied through the fluid inlet, the flow of fluid removed through the fluid outlet, the wash liquid from washing device and the liquid removal device

5. The substrate processing apparatus of claim 1 further comprising a reagent supply in communication with the fluid inlet.

6. The substrate processing apparatus of claim 1 further comprising a substrate handler adapted to manipulate the substrate holder and insert the substrate into the processing chamber and withdraw the substrate from the processing chamber.

7. The substrate processing apparatus of claim 1 wherein the processing chamber is vertically oriented.

8. The substrate processing apparatus of claim 1 further comprising a reagent supply in communication with the fluid inlet, the reagent supply comprising linear molecules.

9. The substrate processing apparatus of claim 1 wherein the liquid removal device is a drying device.

10. A method for forming an analytical device, the method comprising:
(a) inserting a substrate holder and a substrate through an opening in a processing chamber;
(b) supplying a reagent into the processing chamber and coating the substrate with the reagent to form a coated substrate;
(c) washing the coated substrate with a wash liquid after b) while the coated substrate is within the processing chamber; and
(d) removing the coated substrate from the processing chamber, and removing the wash liquid from the coated substrate as the substrate is being removed from the processing chamber.

11. The method of claim 10 wherein removing the wash liquid comprises drying the substrate as it is being removed from the processing chamber.

12. The method of claim 10 wherein the reagent is a liquid reagent and comprises linear molecules.

13. The method of claim 10 wherein the processing chamber is configured to receive and process only one substrate at a time.

14. The method of claim 10 further comprising, after (d):
forming an array of chemical or biological molecules on the coated substrate.

15. The method of claim 10 wherein the coated substrate includes the substrate and a self-assembled monolayer.
